(19) United States
(12) Patent Application Publication
(10) Pub. No.: US 2018/0052481 A1
(43) Pub. Date: Feb. 22, 2018

(54) METHOD FOR ULTRA-LOW-POWER AND HIGH-PRECISION REFERENCE GENERATION

(71) Applicant: Vidatronic Inc., College Station, TX (US)

(72) Inventors: Mohamed Mostafa Saber ABOUDINA, Giza (EG); Moises Emanuel ROBINSON, College Station, TX (US); Mohamed Ahmed Mohamed EL-NOZAHI, Giza (EG); Faisal Abdelatif Elsedeek HUSSIEN, Cairo (EG); Sameh Sameh IBRAHIM, Cairo (EG)

(73) Assignee: Vidatronic Inc., College Station, TX (US)

(21) Appl. No.: 15/679,634

(22) Filed: Aug. 17, 2017

Related U.S. Application Data
(60) Provisional application No. 62/376,358, filed on Aug. 17, 2016.

(51) Int. Cl. G05F 3/26; G05F 3/18; G05F 3/30

(52) U.S. Cl. CPC G05F 3/267; H03F 3/3038; G05F 3/30; G05F 3/185

(57) ABSTRACT

A reference generation circuit includes a reference circuit and a local supply regulation circuit connected between an input supply and the reference circuit to supply a local regulated input to the reference circuit. The local supply regulation circuit comprises an error amplifier and a pass device, and wherein the error amplifier senses an output voltage of the pass device and an output voltage of the reference generation circuit to generate an output to control a gate terminal of the pass device. The error amplifier uses a feedback network to sense the output voltage of the pass device for comparison with the output voltage of the reference generation circuit to generate the output to control the pass

### CROSS REFERENCE TO RELATED APPLICATION

This Claims the benefit of Provisional Application No. 62/376,358, filed on Aug. 17, 2016, the disclosure of which is incorporated by reference in its entirety.

### BACKGROUND

A reference generation circuit is a crucial module for most electronic circuits. Such reference generation circuit may provide reference voltages and/or reference currents that are process, supply and temperature independent, or in some cases the reference currents may be inversely proportional to the value of a reference resistor.

There are factors, such as power consumption, accuracy, power supply rejection and noise tradeoff, that influence the architectural choice of a reference circuit.

FIG. 1 shows a prior art reference generation circuit (100), which provides an accurate, bipolar-based reference voltage. The circuit is supplied by V_{IN} (101.a) and GND (101.b). The current mirror, consisting of PMOS devices M₁ (103), M₂ (104) and M₃ (105), guarantees equal currents through all these three PMOS devices. The opamp O₁ (113) guarantees equal voltages at its inputs. The three components: R₃ (109), Q₁ (107) and Q₂ (110) generate a current that is Proportional To Absolute Temperature (PTAT) through R₃ (109). Currents flowing through R₁ (106) and R₂ (108) are both Complementary To Absolute Temperature (CTAT). The total current I_{T} (112) is adjusted to have a temperature coefficient that is the inverse of the temperature coefficient of the sheet resistance used for R₁, R₂, and R₃ by adjusting the ratio between the different components: R₁, R₂, R₃, Q₁, and Q₂, R₁ and R₂ are usually equal. The output Vₒᵤₜ (102) represents an accurate bandgap voltage that has nearly zero temperature coefficient at the expense of power consumption. The low frequency power supply rejection of this circuit can be made extremely high by increasing the opamp O₁ (113) DC-gain.

Offset voltage at the input of opamp O₁ (113) and current mismatches in the current mirror composed of PMOS devices M₁ (103), M₂ (104) and M₃ (105) contribute to the inaccuracy of the output voltage Vₒᵤₜ (102). Extra power consumption is needed to improve the output voltage accuracy. Therefore, low power, high-accuracy output voltage using this topology is not possible.

FIG. 2. Shows a prior art reference generation circuit (200), which provides a bipolar-less reference voltage. This circuit provides an extremely low power consumption reference circuit, while resulting in moderate to low accuracy output voltages. The circuit is supplied by V_{IN} (201) and GND (202) and consists of three main parts: a PTAT voltage generator (203), a voltage-to-current converter (204) to produce a PTAT current, and finally an output voltage generator (205) to combine the PTAT current with a negative temperature coefficient component to produce a zero temperature coefficient output voltage Vₒᵤₜ (206). This voltage reference circuit generator consumes very small quiescent currents and provides a stable output over temperature, while suffering from medium supply rejection due to the absence of an opamp and from large output voltage variations over process corners. Therefore, this topology is not suitable for high-accuracy, low-power applications.

While these prior art implementations serve their purposes, they fail to achieve low-power and high-accuracy at the same time. Therefore, there is still a need for better reference generation circuits with high accuracy and low power consumption.

### SUMMARY

In general, in one aspect, the invention relates to a novel architecture to enhance the accuracy of ultra-low power reference generation circuits. A reference generation circuit of the invention may provide reference voltages and/or reference currents that are process, supply and temperature independent.

In one aspect, the invention relates to reference generation circuits. A reference generation circuit in accordance with one embodiment of the invention comprises a reference circuit and a local supply regulation circuit connected between an input supply and the reference circuit to supply a local regulated input to the reference circuit.

In accordance with some embodiments of the invention, the local supply regulation circuit comprises an error amplifier and a pass device, and wherein the error amplifier senses an output voltage of the pass device and an output voltage of the reference generation circuit to generate an output to control a gate terminal of the pass device.

In accordance with some embodiments of the invention, the error amplifier uses a feedback network to sense the output voltage of the pass device for comparison with the output voltage of the reference generation circuit to generate the output to control the pass device. The feedback network comprises a potential/voltage divider.

In accordance with some embodiments of the invention, the error amplifier is a skewed amplifier. The skewed error amplifier comprises a differential pair of transistors with a mismatch in dimensions of 1:K₂ and a current mirror consisting of another differential pair with a mirroring ratio of K₁:1, wherein K₂=1/K₁.

In accordance with some embodiments of the invention, the reference circuit comprises a master reference circuit and a slave reference circuit, wherein the slave reference circuit is more power efficient than the master reference circuit, and wherein the master reference circuit is turned on only during start-up or during reset to calibrate the slave circuit to a specific voltage (or current) level.

Another aspect of the invention relates to methods for generating a reference voltage or current using a reference generation circuit comprising a reference circuit and a local supply regulation circuit, wherein the local supply regulation cicuit comprises an error amplifier and a pass device. A method in accordance with one embodiment of the invention comprises sensing an output of the pass device and an output of the reference generation circuit; comparing, using the error amplifier, the output of the pass device and the output of the reference generation circuit to generate an output of the error amplifier; controlling a gate of the pass device, using the output of the error amplifier, to produce a local regulated signal from the pass device; and controlling, using the local regulated signal from the pass device, the reference circuit to generate the reference voltage or current.

Other aspects of the invention would become apparent with the attached drawings and the following description.

### BRIEF DESCRIPTION OF DRAWINGS

The appended drawings illustrate several embodiments of the invention and are not to be considered limiting of its scope, for the invention may admit to other equally effective embodiments.

FIG. 1 shows a schematic diagram of a prior art bipolar-based reference generation circuit.

FIG. 2 shows a schematic diagram of a prior art bipolar-less reference generation circuit.

FIG. 3 shows a block diagram of a reference generation circuit with improved PSR in accordance with one embodiment of the invention.

FIG. 4 shows a schematic of a reference generation circuit with improved PSR using a PMOS pass device in accordance with one embodiment of the invention.

FIG. 5 shows a schematic of a reference generation circuit with improved PSR using a PMOS pass device and using a skewed error amplifier in accordance with one embodiment of the invention.

FIG. 6 shows the input-output characteristics of the skewed error amplifier.

FIG. 7 shows a skewed error amplifier implementation in CMOS technology.

FIG. 8 shows a calibration circuit for an inaccurate reference generation circuit.

FIG. 9 shows a timing diagram of the calibration circuit in accordance with one embodiment of the invention.

FIG. 10 shows a calibration of an inaccurate reference driving multiple loads using an accurate master reference in accordance with one embodiment of the invention.

### DETAILED DESCRIPTION

Aspects of the present disclosure are shown in the above-identified drawings and are described below. In this description, like or identical reference numerals are used to identify common or similar elements. The drawings are not necessarily to scale and certain features may be shown exaggerated in scale or in schematic in the interest of clarity and conciseness.

Embodiments of the invention relate to an accurate low-power reference generation circuit. This invention enables generation of high-quality ultra-low power and high accuracy reference generation circuits, which are required for multiple low power applications, including Internet of Things (IoT) applications. In one or more embodiments of the invention, a master reference circuit with high accuracy is available and used to calibrate a low power, low accuracy reference circuit, named slave reference circuit. In one or more embodiments of this invention, the calibration scheme is independent of the type of slave and master reference circuits. In one more embodiment of the invention, an accurate voltage reference is applied to a package pin used for test purposes.

In one or more embodiments of the invention, the power supply rejection (PSR) of any reference circuit is improved by creating a local regulated supply.

In one or more embodiments, the accurate low-power reference circuit is implemented on a microchip, such as in semiconductor integrated circuits. Throughout this disclosure, the terms “reference circuit,” “reference generation circuit,” “bandgap reference circuit,” “bandgap reference circuit generator,” and “bandgap circuit” may be used interchangeably depending on the context.

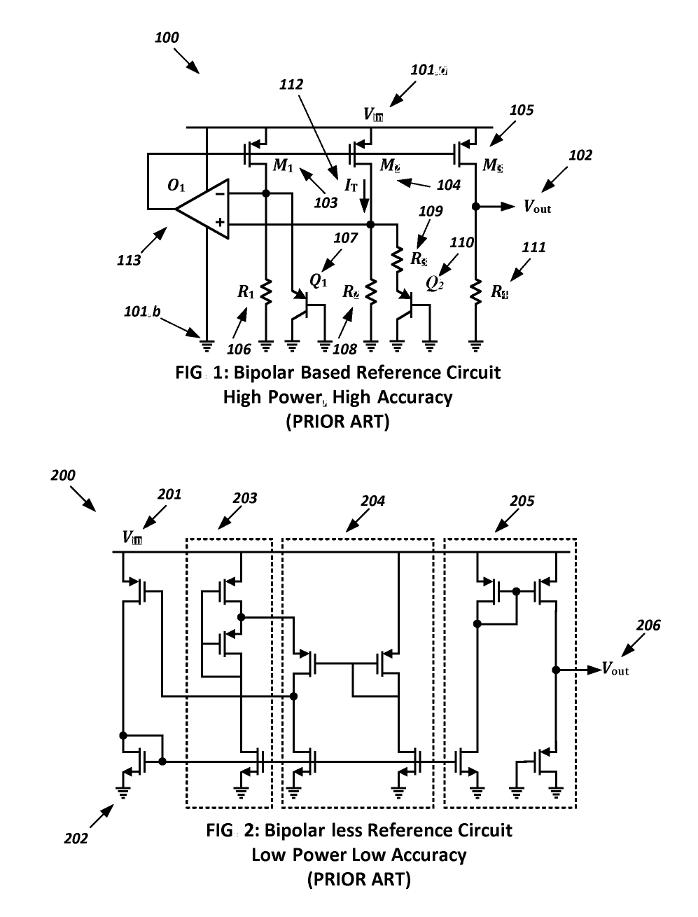

As noted above, FIG. 1 shows a prior art accurate bandgap reference circuit generator that achieves accurate output voltages, while consuming power levels not suitable for ultra-low-power solutions. FIG. 2 shows a prior art ultra-low-power voltage reference generation circuit, while achieving moderate accuracies it is not suitable for most high-accuracy systems.

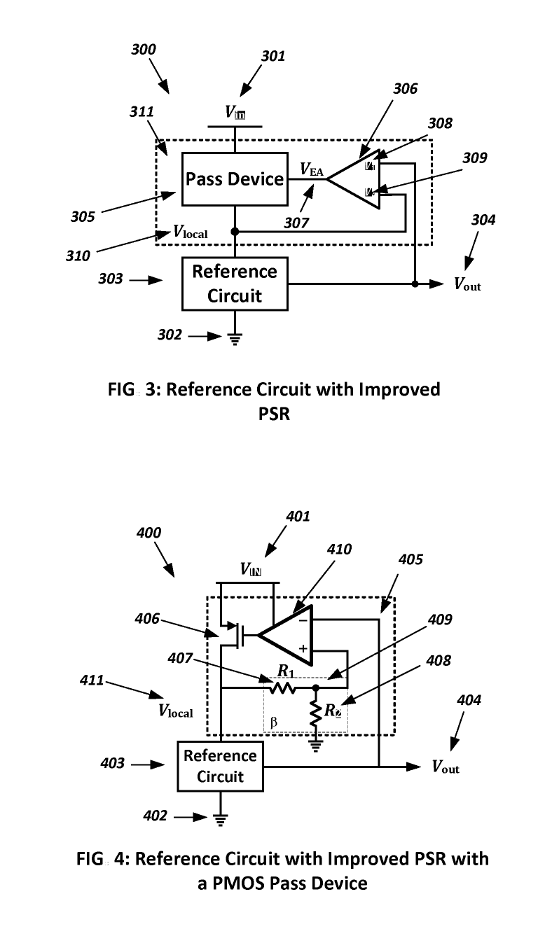

In order to improve supply rejection behavior, FIG. 3 shows a block diagram of a reference generation circuit (300) with improved power supply rejection using a local regulated supply based on the circuit output in accordance with one embodiment of the invention. The circuit is supplied by V_{IN} (301) and GND (302). V_{IN} (301) may also be referred to as an input supply in this description. The reference generation circuit/block (303) can be any suitable reference circuit (e.g., the bipolar reference generation circuit (100) shown in FIG. 1, or the bipolar-less reference generation circuit (200) shown in FIG. 2). The input supply of the reference circuit (303), named V local (310), is produced by a local supply regulation circuit (311) that senses V local (310) as well as Vₒᵤₜ (304) and feeds them into the inputs of the error amplifier circuit (306): V₂ (309) and V₁ (308), respectively, to produce an output of this error amplifier V_{EA} (307) such that V_{EA}=f(V₁,V₂). The local regulated supply voltage is passed through a pass device (305). The relationship between V_{local} and Vₒᵤₜ depends on the implementation and function of the error amplifier. As a result, if the local supply regulation circuit (311) provides a supply rejection of PSR(reg)=ΔV_{local}/ΔV_{IN} and the reference circuit (303) provides a supply rejection of PSR(ref)=ΔVₒᵤₜ/ΔV_{local} then the overall circuit provides a supply rejection of PSR(total)=PSR(reg)+PSR(ref). Possible implementations of the pass device (305) may include any suitable transistor devices, including the field effect types (FET) or the bipolar junction types (BJT). Examples of these include, but are not limited to, NMOS, PMOS, NFIN, PFIN, npn BJT, and pnp BJT.

In accordance with embodiments of the invention, FIG. 4 shows an exemplary implementation (400) for the idea presented in FIG. 3 (300). The circuit (400) is supplied with V_{IN} (401) and GND (402). The local regulator circuit (405) comprises a feedback network (409) and an error amplifier (410). The feedback network consists of a potential divider (voltage divider) R1 (407) and R2 (408). The output of this feedback network is then compared with the Vₒᵤₜ signal (404) through the error amplifier (410). As a result, V_{local} can be expressed as

$$36 {V}_{local} = {V}_{out} \times \frac{{R}_{1} + {R}_{2}}{{R}_{2}} .$$

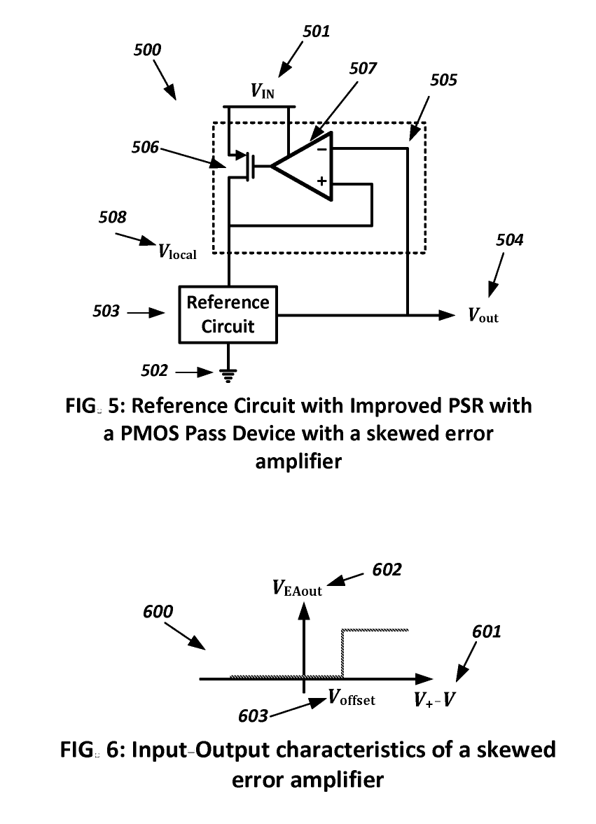

FIG. 5 shows another implementation (500) that does not use feedback network resistors and hence is suitable for use in ultra-low-power systems. FIG. 5 is a low-power implementation of the proposed circuit in (300). The circuit is supplied by VIN (501) and GND (502). The local regulator (505) comprises a skewed error amplifier (507) with an input/output transfer function shown in FIG. 6 (600) and a PMOS pass transistor (506). The output of the skewed error amplifier (507) controls the gate terminal of the pass transistor (506) to produce the proper V_{local}. FIG. 6 shows the input (601)-output (602) characteristics (600) of the skewed error amplifier used in FIG. 5 (507). The response has a high gain at a differential input (601) of a value of V_{offset} (603). As a result, the output V_{local} (508) of the circuit in (500) will relate to Vₒᵤₜ (504) as follows: V_{local}=Vₒᵤₜ+V_{offset}.

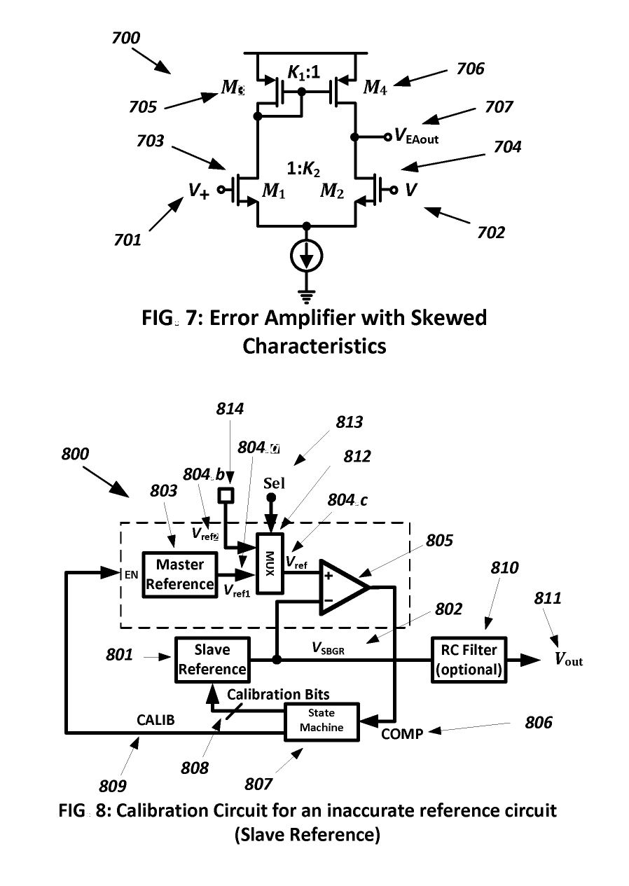

FIG. 7 shows a CMOS implementation example (700) of a skewed error amplifier (507) used in FIG. 5, the input/output characteristics of which resembles that of FIG. 6 (600). V₊ (701) and V_ (702) are the differential inputs of the error amplifier. The skewed error amplifier circuit consists of a differential pair M₁ (703) and M₂ (704) with a mismatch in dimensions of 1:K₂ and a current mirror consisting of transistors M₃ (705) and M₄ (706) with a mirroring ratio of K_{1:1}, wherein K₂₌1/K₁. Accordingly, the output V_{EAout} (707) will relate to the inputs (701) and (702) with a function similar to the skewed error amplifier in (600), where V_{offset} (603) is a function of K₁ and K₂.

FIG. 8 shows a schematic block diagram of proposed reference generation circuit (800) that creates an accurate voltage reference, while consuming ultra-low current levels in the normal mode of operation. The block diagram comprises an ultra-low power reference circuit generator, named slave reference circuit (801) that provides a stable output V_{SBGR} (802) over temperature, while achieving a high PSR using any of the techniques proposed in (300), (400) and (500). The output of this slave reference circuit (801) can be digitally controlled using a digital code (808). The output V_{SBGR} changes proportional to the digital code. For a fixed digital code, the output V_{SBGR} varies with the silicon process corner and hence is not accurate enough.

The embodiment shown in FIG. 8 further comprises an accurate reference circuit, named master reference (803) that is used to provide an accurate output level V_{ref1} (804.a). In case of the availability of an extra external PAD (814), an external reference voltage can be provided V_{ref2} (804.b). The multiplexer (MUX) (812) selects one of the two references, based on the value of the digital selector signal Sel (813), and passes it to V_{ref} (804.c) to calibrate the slave reference circuit. The master reference circuit is enabled only at the start of operation or during a reset condition to calibrate the slave reference circuit.

At startup, V_{SBGR} is compared to the reference voltage V_{ref} using an accurate comparator (805). The output of the comparator COMP (806) controls a digital state machine (807) that changes the digital code (808) to match V_{SBGR} as close as possible to the reference voltage V_{ref}. Once this is achieved the state machine (807) sends a signal CALIB (809) to the master reference (803) as well as the comparator (805) to turn both of them OFF. Therefore, during normal operations, the master reference block and the comparator are turned OFF, resulting in an accurate, high-PSR, ultra-low power V_{SBGR} output.

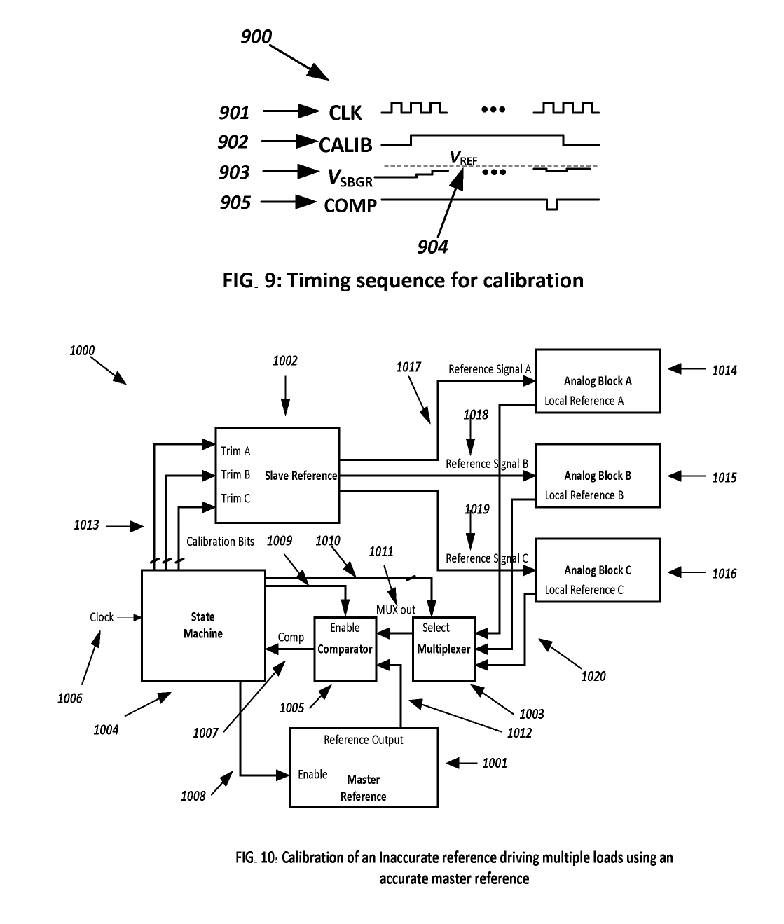

FIG. 9 shows a timing diagram (900) that controls the operation of the calibration loop in (800). The CLK signal (901) dictates the speed of calibration. The CALIB signal (902) is high as long as the calibration cycle is in progress and functions as the signal that enables the master reference block and comparator. At the beginning of the calibration cycle, V_{SBGR} (802) will be lower (or higher) than V_{ref} (804.c). FIG. 9 shows an example when V_{SBGR} (802) is lower than V_{ref} (804.c), but the same principle applies for the opposite case. The state machine (807) keeps changing the digital code (808) as long as V_{SBGR} (802) is lower (or higher) than V_{ref} (804.c). Once this condition is violated, that is, V_{SBGR} (802) is no longer lower or higher than V_{ref}, the calibration is done, and the master reference and comparator are turned OFF to save power consumption.

In one or more embodiments of the invention, a state machine is used to select the digital code (807) that minimizes the difference between V_{SBGR} (802) and V_{ref} (804.c). Those skilled in the art, can adapt the state machine to allow V_{SBGR} (803) to track the V_{ref} (804.c) regardless of the initial value of V_{SBGR} (803) with respect to V_{ref} (804.c).

In one or more embodiments of the invention, the calibration code (808) should provide a range of values for V_{SBGR} (802) that covers the value of V_{ref} (804.c).

FIG. 10 shows a block diagram (1000) of a system that uses the idea described in FIG. 8 (800) to calibrate multiple analog blocks in a system. The block diagram comprises an accurate Master Reference (1001) that is used to calibrate a Slave Reference (1002) that has multiple Reference Signal outputs (1017, 1018, 1019). This example shows the three outputs (1017, 1018, 1019) driving three Analog Blocks (1014, 1015, 1016). This is for illustration only. In general, the number of outputs can be any value equal to or greater than two.

The multiple outputs (1017, 1018, 1019) of the Slave Reference (1002) may be calibrated individually under the control of a State Machine (1004). Block diagram (1000) shows a system that calibrates the Slave Reference (1002) outputs (1017, 1018, 1019) sequentially as an example. However, the system can be implemented to calibrate all of the outputs (1017, 1018, 1019) in parallel by adding an additional comparator (1005) for each output and by removing the multiplexer (1003).

The operation of the calibration of the system (1000) is controlled by the Clock (1006). After power-up or reset, the State machine (1004) enables the Master Reference (1001) and Comparator (1005) with Enable signals (1008) and (1009). One of the three Local Reference signals (1020) is selected based on a Select input (1010) from the State Machine (1004) to drive the output of the Multiplexer (1003), Mux out (1011). The Comparator (1005) compares Mux out (1011) with the Reference Output (1012) of the Master Reference (1001). The output of the Comparator (1005), Comp (1007) is an input to the State Machine (1004). The State Machine (1004) adjusts the Calibration Bits (1013) corresponding to the Analog Block (1014, 1015, 1016) being calibrated. When the State Machine (1004) determines that the Local Reference signal (1020) is close enough to the Master Reference (1001) Reference Output (1012), calibration of the selected Local Reference Signal (1020) is complete, and the State Machine (1004) changes the Select input (1010) of the Multiplexer (1003) to perform calibration on the next Local Reference Signal (1020).

After all of the Local Reference Signals (1020) have been calibrated, the State Machine (1004) turns off the Comparator (1005) and the Master Reference (1001) to save power. After the power-up or reset calibration sequence has been completed, the State Machine (1004) can optionally perform periodic calibration sequences. The periodic calibration may be needed due to drift in environmental conditions, such as temperature or voltage, or due to aging of the components that generate the Local Reference Signals (1020).

This block diagram (1000) shows a system that calibrates the value of Local Reference Signals (1020) that are generated in the Analog Blocks (1014, 1015, 1016) instead of calibrating the value of the Reference Signals (1017, 1018, 1019) generated by the Slave Reference (1002). This is done to reduce or eliminate errors due to component mis-match in the Analog Blocks (1014, 1015, 1016), I-R drop in the Local Reference Signals (1020), and/or power-supply or ground voltage differences between the Slave Reference (1002) and the Analog Blocks (1014, 1015, 1016).

While the invention has been described with respect to a limited number of embodiments, those skilled in the art, having the benefit of this disclosure, will appreciate that other embodiments can be devised which do not depart from the scope of the invention as disclosed herein. Accordingly, the scope of the invention should be limited only by the attached claims.

What is claimed is:

1. A reference generation circuit, comprising:
a reference circuit; and
a local supply regulation circuit connected between an input supply and the reference circuit to supply a local regulated input to the reference circuit.

2. The reference generation circuit according to claim 1, wherein the local supply regulation circuit comprises an error amplifier and a pass device, and wherein the error amplifier senses an output voltage of the pass device and an output voltage of the reference generation circuit to generate an output to control a gate terminal of the pass device.

3. The reference generation circuit according to claim 2, wherein the error amplifier uses a feedback network to sense the output voltage of the pass device for comparison with the output voltage of the reference generation circuit to generate the output to control the pass device.

4. The reference generation circuit according to claim 3, wherein the feedback network comprises a potential divider.

5. The reference generation circuit according to claim 2, wherein the error amplifier is a skewed error amplifier.

6. The reference generation circuit according to claim 2, wherein the skewed error amplifier comprises a differential pair of transistors with a mismatch in dimensions of 1:K₂ and a current mirror consisting of another differential pair of with a mirroring ratio K₁:1, wherein K₂=1/K₁.

7. The reference generation circuit according to claim 1, wherein the reference circuit comprises a master reference circuit and a slave reference circuit, wherein the slave reference circuit is more power efficient than the master reference circuit, and wherein the master reference circuit is turned on only during startup or reset to calibrate the slave circuit to a specific level.

8. The reference generation circuit according to claim 7, wherein the slave reference circuit has multiple reference signal outputs for calibrating multiple analog blocks in a system.

9. The reference generation circuit according to claim 1, wherein the pass device is selected from the group consisting of NMOS, PMOS, NFIN, PFIN, npn BJT, and pnp BJT.

10. A method for generating a reference voltage or current using a reference generation circuit that comprising a reference circuit and a local supply regulation circuit, wherein the local supply regulation unit comprises an error amplifier and a pass device, the method comprising:
sensing an output of the pass device and an output of the reference generation circuit;
comparing, using the error amplifier, the output of the pass device and the output of the reference generation circuit to generate an output of the error amplifier;
controlling a gate of the pass device, using the output of the error amplifier, to produce a local regulated signal from the pass device; and
controlling, using the local regulated signal from the pass device, the reference circuit to generate the reference voltage or current.

11. The method according claim 10, wherein the reference circuit comprises a master reference circuit and a slave reference circuit, the method further comprising: calibrating the slave reference circuit using the master reference circuit.

12. The method according claim 11, further comprising: generating multiple reference output signals with the slave reference circuit to control multiple analog blocks in a system.
